(19) United States
(12) Patent Application Publication
(10) Pub. No.: US 2007/0155080 A1
(43) Pub. Date: Jul. 5, 2007

(54) THIM FILM TRANSISTOR SUBSTRATE AND MANUFACTURING METHOD THEREOF

(75) Inventor: Ju Ae YOON, Seongnam-si, Gyeonggi-do (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/618,028

(22) Filed: Dec. 29, 2006

(30) Foreign Application Priority Data
Dec. 29, 2005 (KR) 10-2005-0133698

(51) Int. Cl. H01L 21/336; H01L 21/8234

(52) U.S. Cl. 438/197

(57) ABSTRACT

A TFT substrate and manufacturing method thereof disclose a simplified manufacturing process wherein an undercut phenomenon of an active layer can be prevented. A method of manufacturing a TFT substrate includes a first mask process of forming a gate metal pattern including a gate line and a gate electrode connected to the gate line on a substrate, a second mask process of forming a gate insulating layer covering the gate line and the gate electrode, a semiconductor pattern including an active layer and an ohmic contact layer on the gate insulating layer, and a source/drain metal pattern on the semiconductor pattern, the source/drain metal pattern including a data line defining a pixel region by intersecting the gate line, a source electrode connected to the data line, and a drain electrode exposing the active layer and facing the source electrode with a channel region disposed therebetween, and a third mask process of forming a passivation layer covering the source/drain metal pattern, a pixel hole penetrating the active layer exposed by the passivation layer and by the drain electrode, and a pixel electrode connected to the drain electrode within the pixel hole.

This application claims priority to Korean Patent Application No. 2005-0133698, filed on Dec. 29, 2005, and all the benefits accruing therefrom under 35 U.S.C. §119, the contents of which in its entirety are herein incorporated by reference.

### BACKGROUND OF THE INVENTION

1. Field of the Invention

The present invention relates to a thin film transistor (“TFT”) substrate applied to a display device and manufacturing method thereof, and more particularly, to a TFT substrate and a simplified manufacturing method thereof, wherein an undercut phenomenon of an active layer is prevented.

2. Description of the Related Art

A liquid crystal display (“LCD”) device displays images by using an electric field to adjust the light transmittance of liquid crystals having dielectric anisotropy. The LCD device includes an LCD panel for displaying an image through a liquid crystal cell matrix and a driving circuit for driving the LCD panel.

Referring to FIG. 1, a conventional LCD panel includes a color filter substrate 10 and a TFT substrate 20 assembled to each other with liquid crystals 24 disposed therebetween.

The color filter substrate 10 includes a black matrix 4, a color filter 6 and a common electrode 8 formed sequentially on an upper glass substrate 2. The black matrix 4 is formed in a matrix shape on the upper substrate 2. The black matrix 4 divides a region of the upper substrate 2 into a plurality of cell regions where the color filter 6 is formed and prevents the light interference between adjacent cell regions and the reflection of external light. The color filter 6 is separately formed into red R, green G and blue B in the cell regions divided by the black matrix 4 to respectively transmit red, green and blue light. The common electrode 8 is a transparent conductive layer deposited on an entire surface of the color filter 6 and supplies a common voltage that serves as a reference voltage during the driving of the liquid crystals 24. For planarization of the color filter 6, an overcoat layer (not shown) may be additionally formed between the color filter 6 and the common electrode 8.

The TFT substrate 20 includes a TFT 18 and a pixel electrode 22 which are formed in every cell region, each cell region defined by an intersection of a gate line 14 and a data line 16 on a lower substrate 12. The TFT 18 supplies a data signal from the data line 16 to the pixel electrode 22 in response to a gate signal from the gate line 14. The pixel electrode 22, formed of a transparent conductive layer, supplies the data signal from the TFT 18 to drive the liquid crystals 24.

The liquid crystals 24 having dielectric anisotropy adjust the transmittance of light by rotating according to an electric field generated by the data signal of the pixel electrode 22 and by the common voltage of the common electrode 8, thereby accomplishing various gray levels.

The LCD panel further includes a spacer (not shown) for maintaining a constant cell gap between the color filter substrate 10 and the TFT substrate 20.

The color filter substrate 10 and the TFT substrate 20 of the LCD panel are formed by a plurality of mask processes. One mask process includes a plurality of processes, such as a thin film deposition (or coating) process, a cleaning process, a photolithographic process, an etching process, a photoresist stripping process, an inspection process, etc.

Especially since the manufacture of the TFT substrate requires not only a semiconductor process but a plurality of mask processes, its manufacturing process becomes complicated and the complexity of the manufacturing process becomes a main factor in the increase of a manufacturing cost of the LCD panel. Therefore, the TFT substrate has been developed toward reducing the number of mask processes necessary its manufacture.

### BRIEF SUMMARY OF THE INVENTION

It is therefore an aspect of the present invention to provide a TFT substrate and manufacturing method thereof, wherein a manufacturing process of the TFT substrate is simplified and an undercut phenomenon of an active layer can be prevented.

In accordance with an exemplary embodiment of the present invention, a method of manufacturing a TFT substrate includes a first mask process of forming a gate metal pattern on a substrate, the gate metal pattern including a gate line and a gate electrode connected to the gate line; a second mask process of forming a gate insulating layer covering the gate line and the gate electrode, a semiconductor pattern including an active layer and an ohmic contact layer on the gate insulating layer, and a source/drain metal pattern on the semiconductor pattern, the source/drain metal pattern including a data line defining a pixel region by intersecting the gate line, a source electrode connected to the data line and a drain electrode exposing the active layer and facing the source electrode with a channel region disposed therebetween; and a third mask process of forming a passivation layer covering the source/drain metal pattern, a pixel hole penetrating the active layer exposed by the passivation layer and by the drain electrode, and a pixel electrode connected to the drain electrode within the pixel hole.

The first mask process further includes forming a storage line overlapping the pixel electrode with the gate insulating layer disposed therebetween to form a storage capacitor.

The semiconductor pattern adjacent to the storage line is exposed by the pixel hole to form a same width as the drain electrode or to form a step shape with the drain electrode.

The second mask process includes depositing an amorphous silicon layer, an impurity doped amorphous silicon layer and a source/drain metal layer on the gate insulating layer; forming a photoresist pattern having a step difference on the source/drain metal layer; patterning the amorphous silicon layer, the impurity doped amorphous silicon layer and the source/drain metal layer by using the photoresist pattern; removing the photoresist pattern of relatively thin thickness by ashing the photoresist pattern; removing the source/drain metal layer and the impurity doped amorphous silicon layer of a storage capacitor region and of the channel region exposed by removing the photoresist pattern of relatively thin thickness; and removing the photoresist pattern.

The third mask process includes forming a photoresist pattern on the passivation layer, forming the pixel hole by etching the passivation layer and the active layer of the pixel region exposed through the photoresist pattern, forming a transparent conductive layer on the passivation layer where the photoresist pattern exists, and forming the pixel electrode by eliminating the photoresist pattern and the transparent conductive layer by a lift-off process.

In accordance with another exemplary embodiment of the present invention, a TFT substrate includes a gate line formed on a substrate, a data line defining a pixel region by intersecting the gate line with a gate insulating layer disposed therebetween; a thin film transistor including a gate electrode connected to the gate line; a source electrode connected to the data line; a drain electrode facing the source electrode; a semiconductor pattern forming a channel between the source electrode and the drain electrode; a passivation layer covering the gate line, the data line and the thin film transistor; a pixel hole of the pixel region penetrating the passivation layer and an active layer included in the semiconductor pattern; and a pixel electrode connected to the drain electrode within the pixel hole.

The TFT substrate further includes a storage line that is formed to cross the pixel region in parallel with the gate line and overlaps the pixel electrode with a gate insulating layer therebetween to form a storage capacitor.

The semiconductor pattern adjacent to the storage line is exposed by the pixel hole to form a same width as the drain electrode or form a step shape with the drain electrode.

### BRIEF DESCRIPTION OF THE DRAWINGS

The above and other aspects, features and advantages of the present invention will become more apparent from the following detailed description when taken in conjunction with the accompanying drawings in which:

FIG. 1 is a perspective view schematically illustrating a conventional LCD panel;

FIG. 2 is a plan view illustrating an exemplary embodiment of part of a TFT substrate according to the present invention;

FIG. 3 is a cross-sectional view taken along lines I-I′, II-II′ and III-III′ in FIG. 2 showing the TFT substrate;

FIGS. 4A and 4B are a plan view and a cross-sectional view, respectively, illustrating an exemplary embodiment of a first mask process of a TFT substrate manufacturing method according to the present invention;

FIGS. 5A and 5B are a plan view and a cross-sectional view, respectively, illustrating an exemplary embodiment of a second mask process of a TFT substrate manufacturing method according to the present invention;

FIGS. 6A to 6D are cross-sectional views taken along lines I-I′, II-II′ and III-III′ in FIG. 5A illustrating the second mask process in more detail;

FIGS. 7A and 7B are a plan view and a cross-sectional view, respectively, illustrating an exemplary embodiment of a third mask process of a TFT substrate manufacturing method according to the present invention;

FIGS. 8A to 8D are cross-sectional views taken along lines I-I′, II-II′ and III-III′ in FIG. 7A illustrating the third mask process in more detail; and

FIGS. 9A and 9B are cross-sectional views illustrating a conventional mask process compared to the process of the present invention.

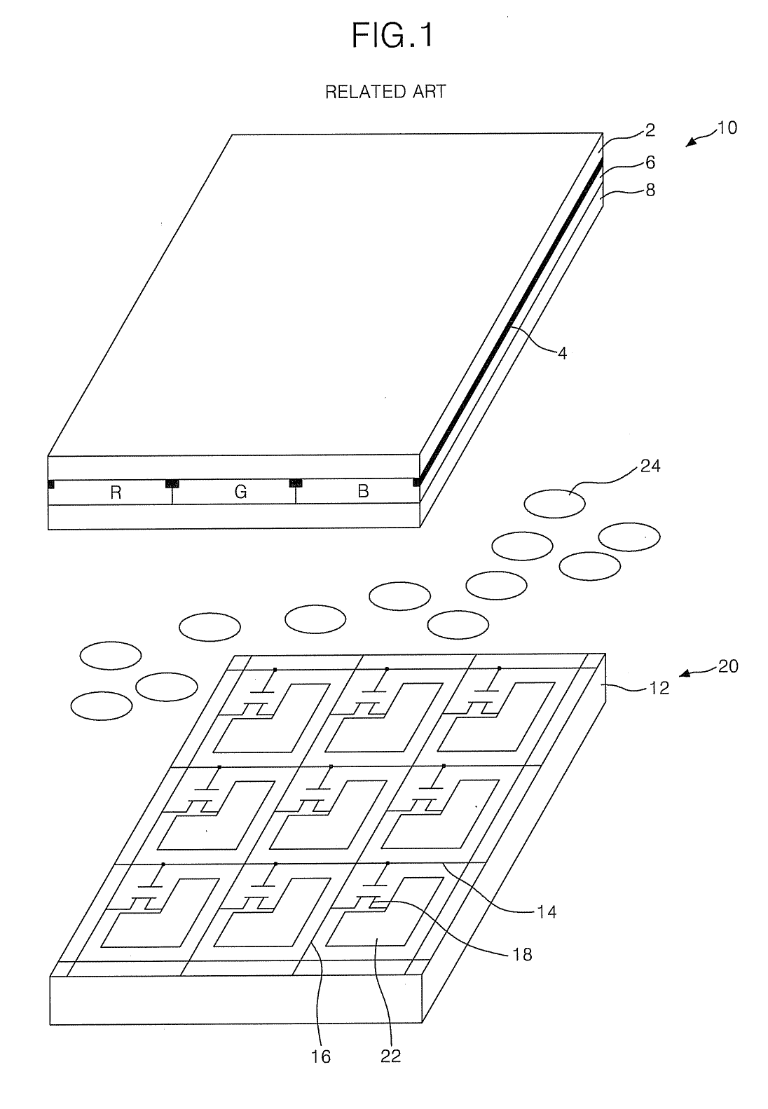

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

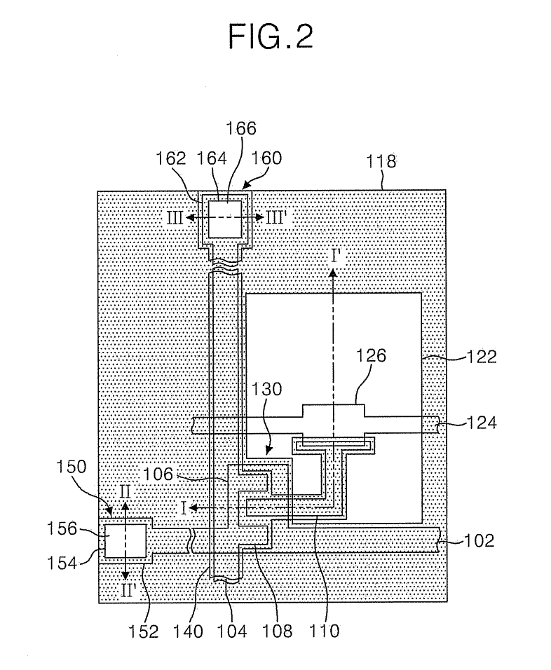

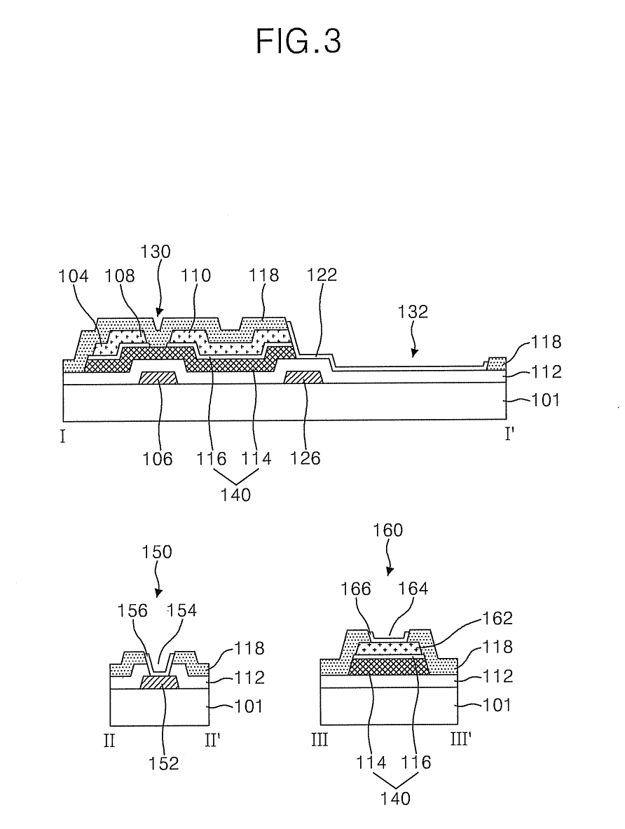

FIG. 2 is a plan view illustrating an exemplary embodiment of part of a TFT substrate according to the present invention, and FIG. 3 is a cross-sectional view taken along lines I-I′, II-II′ and III-III′ in FIG. 2 showing the TFT substrate.

The TFT substrate shown in FIGS. 2 and 3 includes a gate line 102 and a data line 104 formed to intersect each other on a lower substrate 101 with a gate insulating layer 112 disposed therebetween, a TFT transistor 130 adjacent to the intersection, and a pixel electrode 122 formed in a pixel region defined by an intersection of a gate line 102 and a data line 104. The TFT substrate further includes a storage capacitor formed by the overlap between a drain electrode 110 connected to the pixel electrode 122 and a storage electrode 126, a gate pad 150 connected to the gate line 102, and a data pad 160 connected to the data line 104.

The TFT 130 causes a pixel signal applied to the data line 104 to be charged to the pixel electrode 122 and then to be maintained in response to a scan signal applied to the gate line 102. The TFT 130 includes a gate electrode 106 connected to the gate line 102, a source electrode 108 connected to the data line 104, the drain electrode 110 which faces the source electrode 108 and is connected to the pixel electrode 108, an active layer 114 which overlaps the gate electrode 106 with the gate insulating layer 112 disposed therebetween and forms a channel between the source electrode 108 and the drain electrode 110, and an ohmic contact layer 116 formed for an ohmic contact between the source electrode 108 and the drain electrode 110 on the active layer 114, except in a channel region.

A semiconductor pattern 140, including the active layer 114 and the ohmic contact layer 116, is formed to overlap the data line 104.

A pixel hole 132 penetrating a passivation layer 118 is formed in the pixel region defined by an intersection of the gate line 102 and data line 104. The pixel electrode 122 is formed on the gate insulating layer 112 within the pixel hole 132 and is connected to the exposed drain electrode 110. The pixel electrode 122 charges the pixel signal supplied from the TFT 130 and creates a potential difference with a common electrode formed on a color filter substrate (not shown). The potential difference causes liquid crystals between the TFT substrate and the color filter substrate to rotate by dielectric anisotropy and adjust the amount of incident light via the pixel electrode 122 from a light source (not shown) to transmit the light toward the color filter substrate.

The storage capacitor overlaps the storage electrode 126 extending from a storage line 124 with the pixel electrode 122 and the gate insulating layer 112 disposed therebetween. The storage capacitor stably maintains the pixel signal charged to the pixel electrode 118. Since the storage capacitor according to the present invention does not include the semiconductor pattern 140, a variation in a capacitance value caused by the semiconductor pattern is prevented and thus a defect in picture quality, such as a flicker, can be prevented.

The semiconductor pattern 140 of a storage capacitor region is exposed with the same width as the drain electrode 110 by the pixel hole 132 or is exposed to form a step shape with the drain electrode 110. Then a step coverage of the pixel electrode 122 contacting the side surfaces of the semiconductor pattern 140 and of the drain electrode 110 exposed by the pixel hole 132 is improved.

A part of the storage electrode 126 may be overlapped by the drain electrode 110 connected to the pixel electrode 122 with the gate insulating layer 112 and semiconductor pattern 140 disposed therebetween.

The gate line 102 is connected to a gate driver (not shown) through the gate pad 150. The gate pad 150 includes a gate pad lower electrode 152 extended from the gate line 102, and a gate pad upper electrode 156 formed within a first contact hole 154 penetrating the passivation layer 118 and the gate insulating layer 112, and connected to the gate pad lower electrode 152.

The data line 104 is connected to a data driver (not shown) through the data pad 160. The data pad 160 includes a data pad lower electrode 162 extended from the data line 104, and a data pad upper electrode 166 formed within a second contact hole 164 penetrating the passivation layer 118 and connected to the data pad lower electrode 162. The semiconductor pattern 140 including the ohmic contact layer 116 and the active layer 114 is formed under the data pad lower electrode 162 to overlap the data pad lower electrode 162.

In such a TFT substrate, a transparent conductive pattern including the pixel electrode 122, the gate pad upper electrode 156 and the data pad upper electrode 166 forms a boundary with the side surface of the passivation layer 118. Since the side surface of the passivation layer 118 has a gentle slope, the transparent conductive layer remains thereon. Therefore, a problem of exposing a metal layer between the passivation layer 118 and the transparent conductive pattern can be prevented. Since the pixel electrode 122 is formed on the gate insulating layer 112, a step coverage is reduced and a rubbing defect caused by the step coverage of the pixel electrode 122 can be prevented.

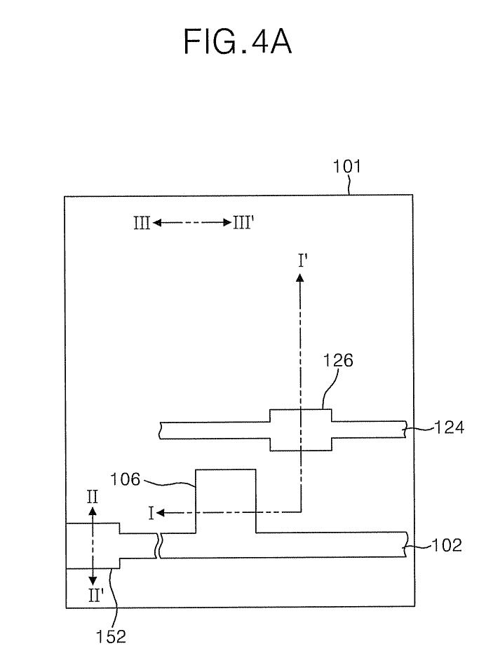

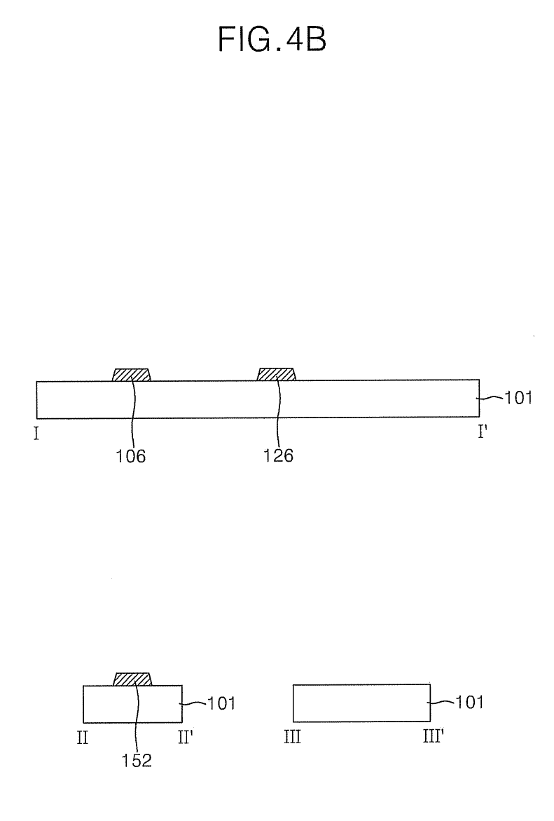

FIGS. 4A and 4B are a plan view and a cross-sectional view, respectively, illustrating an exemplary embodiment of a first mask process of a TFT substrate manufacturing method according to the present invention.

In the first mask process, a first conductive pattern group including the gate line 102, the gate electrode 106 connected to the gate line 102 and the gate pad lower electrode 152, is formed on the lower substrate 101.

Specifically, a gate metal layer is formed on the lower substrate 101 by a deposition method such as sputtering. As the gate metal layer, a metal material, such as molybdenum (Mo), titanium (Ti), aluminum neodymium (AlNd), aluminum (Al), chromium (Cr), Mo alloy, cupper (Cu) alloy, Al alloy, etc., is used in a single layer structure or a multiple layer structure (e.g., two or more layers). The gate metal layer is patterned by a photolithographic process using a first mask and an etching process, thereby forming the first conductive pattern group including the gate line 102, the gate electrode 106 and the gate pad lower electrode 152.

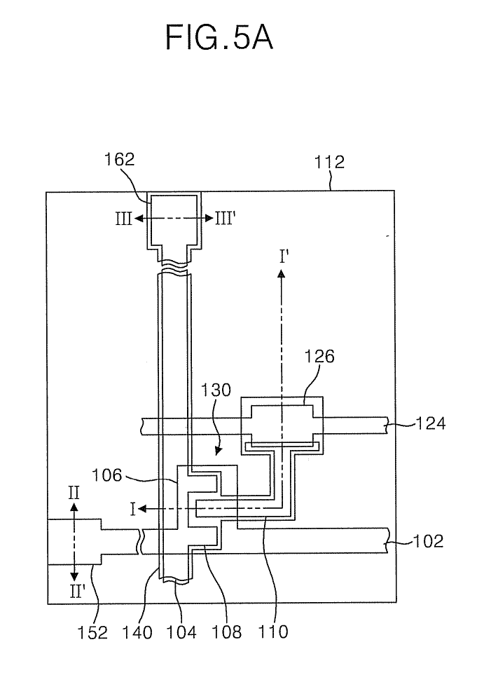

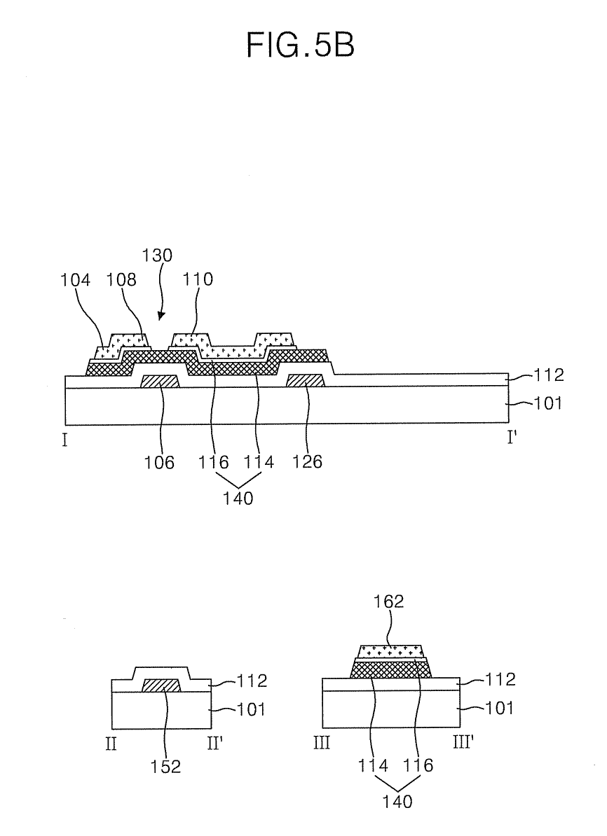

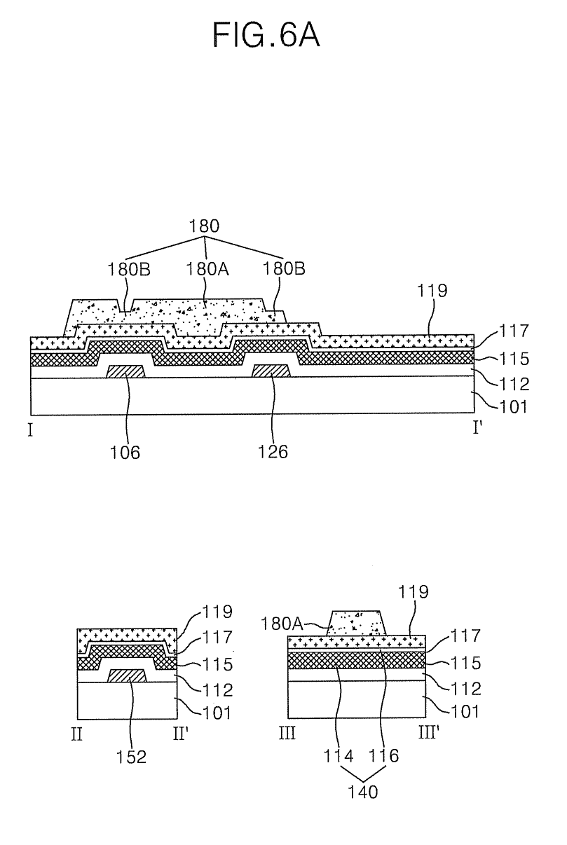

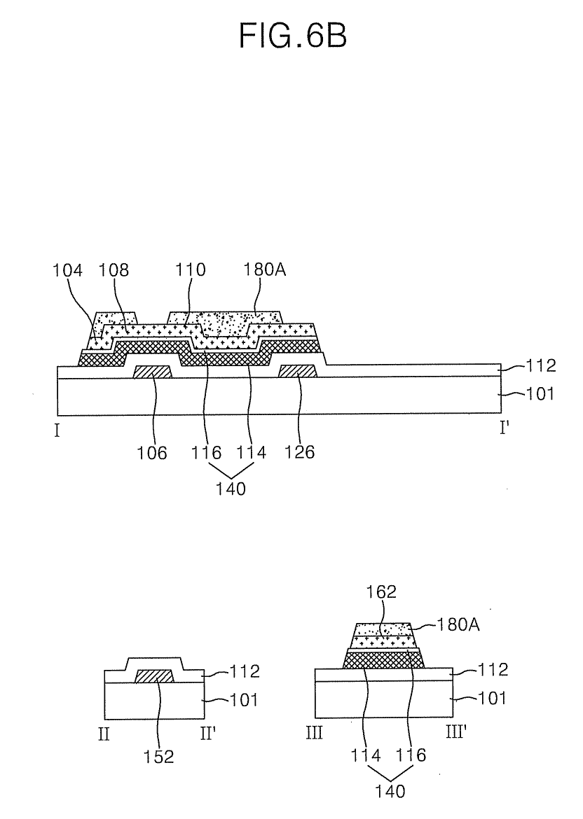

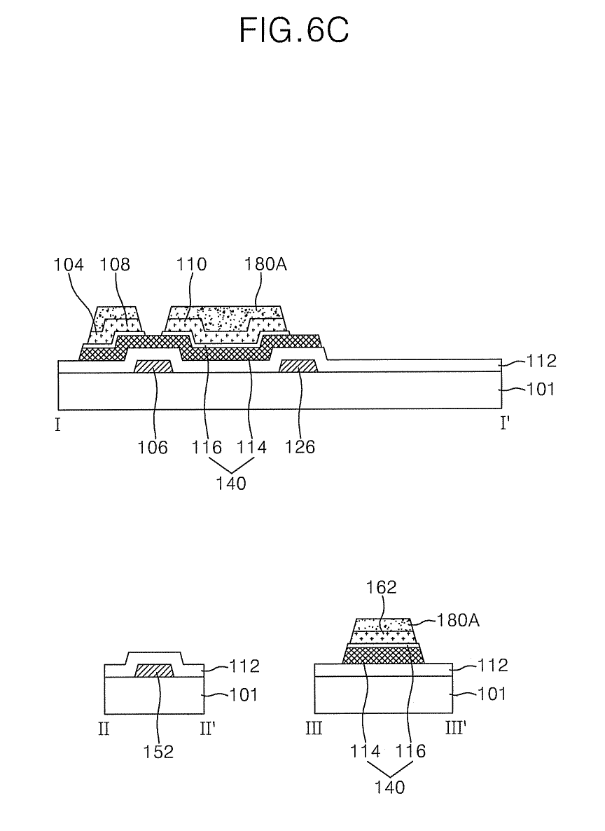

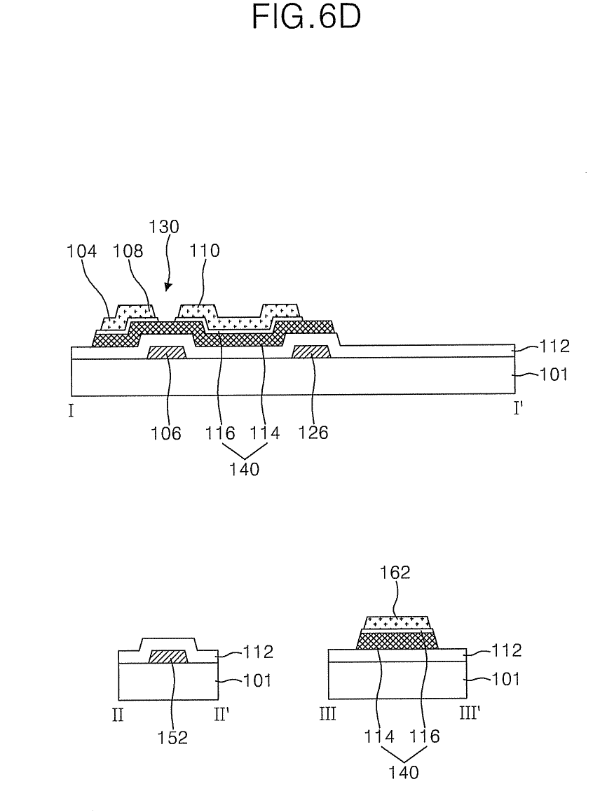

FIGS. 5A and 5B are a plan view and a cross-sectional view, respectively, illustrating an exemplary embodiment of a second mask process of a TFT substrate manufacturing method according to the present invention. FIGS. 6A to 6D are cross-sectional views taken along lines I-I′, II-II′ and III-III′ in FIG. 5A illustrating the second mask process in more detail.

The gate insulating layer 112 is formed on the lower substrate 101 where the first conductive pattern group is formed. A source/drain metal pattern including the data line 104, the source electrode 108, the drain electrode 110 and the data pad lower electrode 162 are formed on the gate insulation layer 112 by the second mask process. Moreover, the semiconductor pattern 140 including the overlapped ohmic contact layer 116, and active layer 114 under the source/drain pattern along the source/drain pattern exposed by the gaps in the ohmic contact layer 116 and in the drain electrode 110 in the storage capacitor region are formed on the gate insulating layer 112 by the second mask process. The semiconductor pattern 140 and the source/drain metal pattern are formed by one mask process using, for example, a diffraction exposure mask or a half-tone mask. Hereinafter, a description will be made of an example using the diffraction exposure mask.

Referring to FIG. 6A, the gate insulating layer 112, an amorphous silicon layer 115, an impurity (n+or p+) doped amorphous silicon layer 117 and a source/drain metal layer 119 are sequentially formed on the lower substrate 101 where the first conductive pattern group has been formed. For example, the gate insulating layer 112, the amorphous silicon layer 115 and the impurity doped amorphous silicon layer 117 are formed by a plasma enhanced chemical vapor deposition (“PECVD”) method, and the source/drain metal layer 119 is formed by a deposition method such as sputtering. An inorganic insulating material, such as silicon oxide (SiOx) or silicon nitride (SiNx) is used as the gate insulating layer 112. A metal material, such as Mo, Ti, Cu, AlNd, Al, Cr, Mo alloy, Cu alloy, Al alloy, etc., is used as the source/drain metal layer 119 in a single layer structure or in a multiple layer structure. A photoresist is coated on the source/drain metal layer 119, and the photoresist is exposed and developed by a photolithographic process using a diffraction exposure mask of a second mask, thereby forming a photoresist pattern 180 having a step coverage.

Specifically, the diffraction exposure mask includes a transparent quartz substrate, a barrier layer formed of a metal such as Cr or chrome oxide (CrOx) on the quartz substrate, and a diffraction exposure slit. The barrier layer is located in a region where the semiconductor pattern and a second conductive pattern group are to be formed and blocks ultraviolet rays. After the photoresist is developed, a first photoresist pattern 180a remains as shown in FIG. 6A. The diffraction exposure slit is located in a region where the channel of the TFT is to be formed and in a region where the drain electrode used as the storage electrode in the storage region is to be formed and diffracts ultraviolet rays. After the photoresist is developed, a second photoresist pattern 180b thinner than the first photoresist pattern 180a remains as shown in FIG. 6A. A transmissive portion of the diffraction exposure mask existing only in the quartz substrate transmits the ultraviolet rays, and after development the photoresist is removed as shown in FIG. 6A.

Referring to FIG. 6B, the source/drain metal layer 119 is patterned by an etching process using the photoresist pattern 180 having a step coverage, thereby forming the source/drain metal pattern and the semiconductor pattern 140. In this case, the source electrode 108 and the drain electrode 110 of the source/drain metal pattern are connected to each other.

Thereafter, the photoresist pattern 180 is ashed by an ashing process using an oxygen (O₂) plasma. Then the first photoresist pattern 180a becomes thinner and the second photoresist pattern is removed. The exposed source/drain metal pattern and the ohmic contact layer 116 under the exposed source/drain metal pattern are removed by an etching process using the ashed first photoresist pattern 180a. Then the source electrode 108 and the drain electrode 110 are separated from each other as shown in FIG. 6C, and the channel region of the TFT and the active layer 114 of the storage capacitor region are exposed. At this time, both sides of the source/drain metal pattern are etched once again along the first photoresist pattern 180a and thus the source/drain metal pattern and the semiconductor pattern 140 have a uniform step coverage in a stair shape. Thereafter, the first photoresist pattern 180a remaining on the source/drain metal pattern is removed by a stripping process as shown in FIG. 6D.

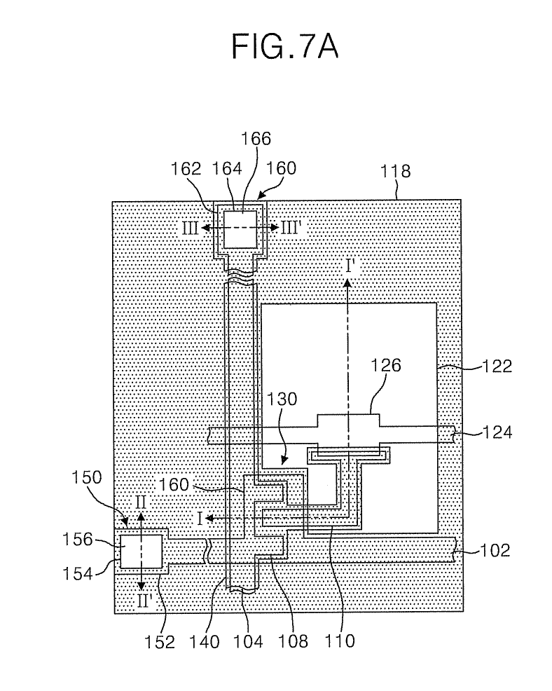

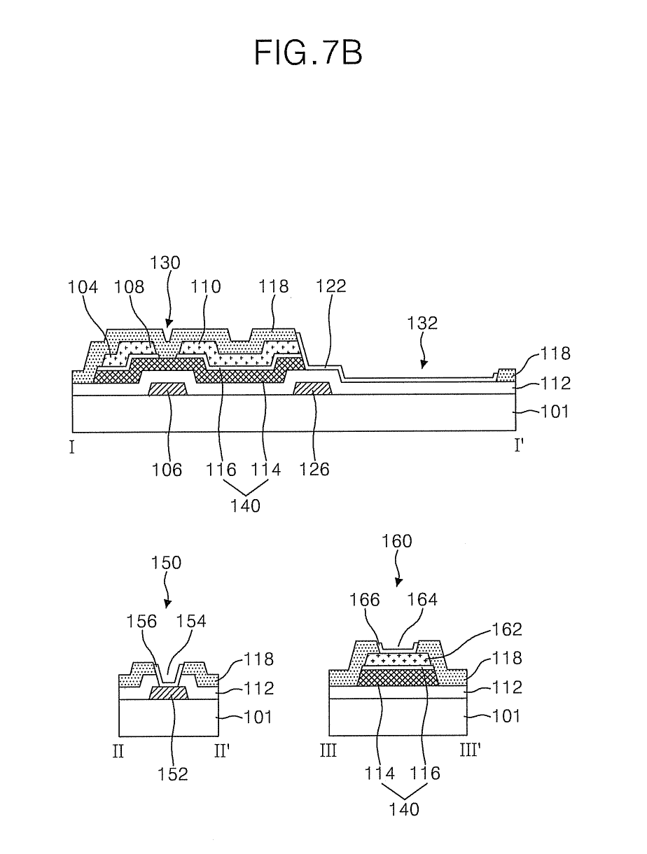

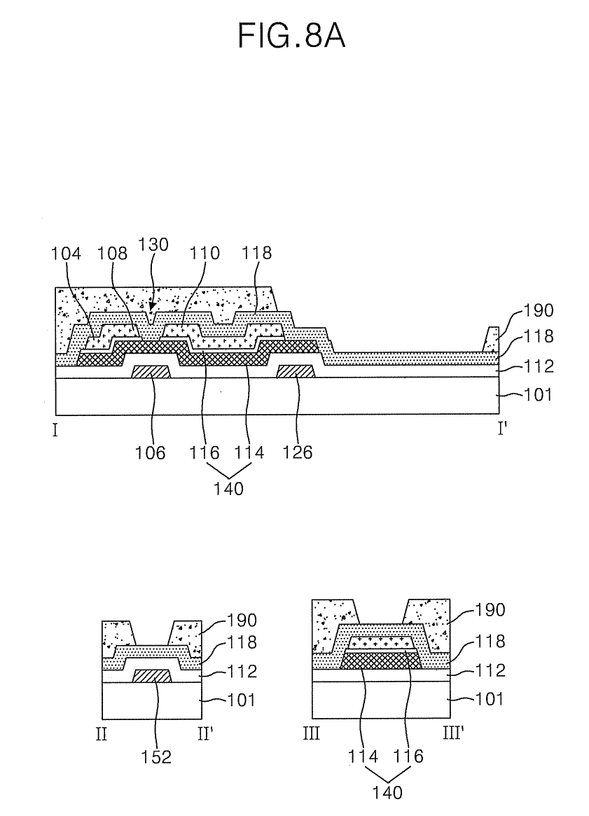

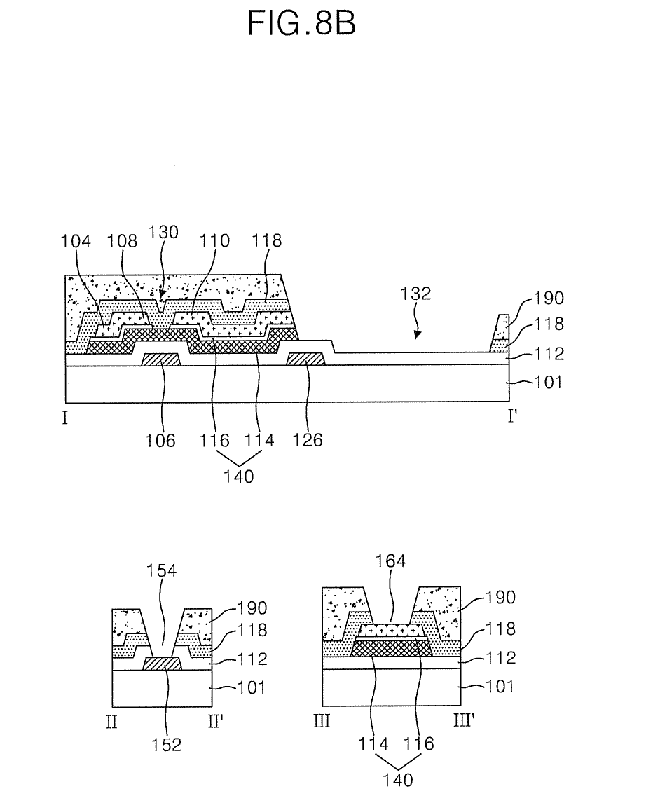

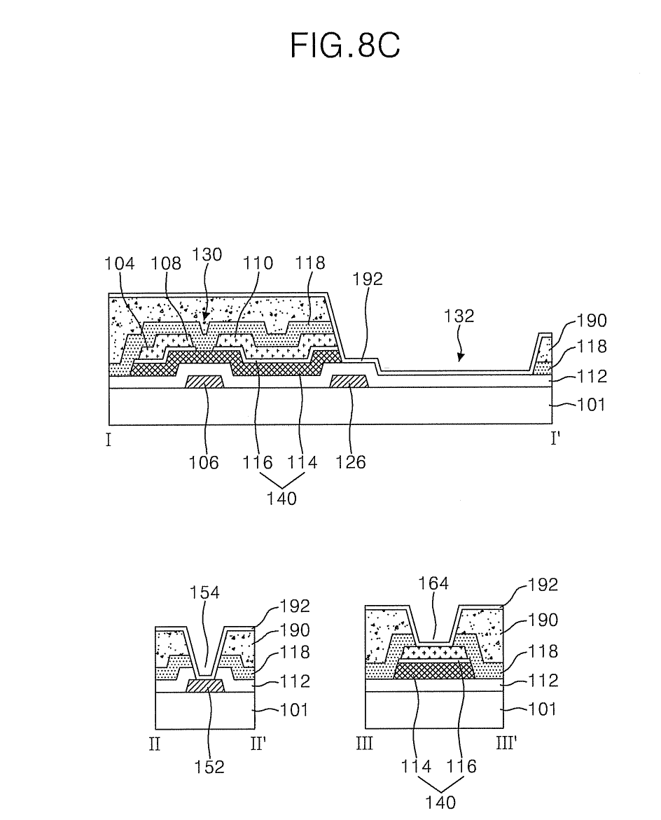

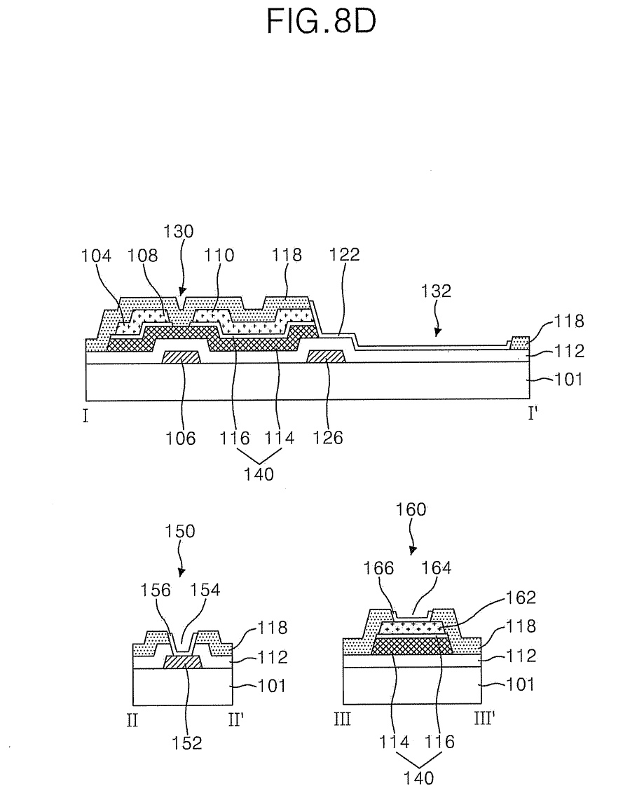

FIGS. 7A and 7B are a plan view and a cross-sectional view, respectively, illustrating an exemplary embodiment of a third mask process of a TFT substrate manufacturing method according to the present invention. FIGS. 8A to 8D are cross-sectional views taken along lines I-I′, II-II′ and III-III′ in FIG. 7A illustrating the third mask process in more detail.

The passivation layer 118 including the pixel hole 132 and the first and second contact holes 154 and 164 are formed, and the transparent conductive pattern including the pixel electrode 122, the gate pad upper electrode 156 and the data pad upper electrode 166 are formed, by the third mask process. The first contact hole 154 penetrates the passivation layer 118 and the gate insulating layer 112, whereas the pixel hole 132 and the second contact hole 164 penetrate only the passivation layer 118.

As illustrated in FIG. 8A, the passivation layer 118 is formed on the gate insulating layer 112 where the source/drain metal pattern is formed by PECVD, spin coating, or spinless coating methods. An inorganic insulating material like the gate insulating layer 112 is used as the passivation layer 118. An organic insulating layer, such as acryl organic compound, bisbenzocyclobutene (BCB) or perfluorocyclobutyl (PFCB), may be used as the passivation layer 118. A photoresist is coated on the passivation layer 118 and the photoresist is exposed and developed by a photolithographic process using a third mask, thereby forming the photoresist pattern 190.

As illustrated in FIG. 8B, the passivation layer 118, the active layer 114 and the gate insulating layer 112 are patterned by an etching process, a dry etching process for example, using the photoresist pattern 190 as a mask, thereby forming the first and second contact holes 154 and 164 and the pixel hole 132. The first contact hole 154 exposes the gate pad lower electrode 152 by penetrating the passivation layer 118 and the gate insulating layer 112. The pixel hole 132 is formed in the pixel region and exposes the drain electrode 110 and the gate insulating layer 112. The second contact hole 164 exposes the data pad lower electrode 162. The first contact hole 154, the pixel hole 132 and the second contact hole 164 each having a different depth can be formed not only by a general exposure mask but by a diffraction exposure mask or a half-tone mask.

Referring to FIG. 8C, a transparent conductive layer 192 is formed to cover the photoresist pattern 190 by a deposition method such as sputtering. As the transparent conductive layer 192, indium-tin-oxide (ITO), tin-oxide (TO), indium-zinc-oxide (IZO), indium-tin-zinc-oxide (ITZO), etc. are used. Thereafter, the areas of photoresist pattern 190 where the transparent conductive layer 192 is coated are removed by a lift-off process as illustrated in FIG. 8D. Since the transparent conductive layer 192 is patterned, the transparent conductive pattern, that is, the pixel electrode 122, the gate pad upper electrode 156 and the data pad upper electrode 166 are formed within the pixel hole 132 and the first and second contact holes 154 and 164, respectively.

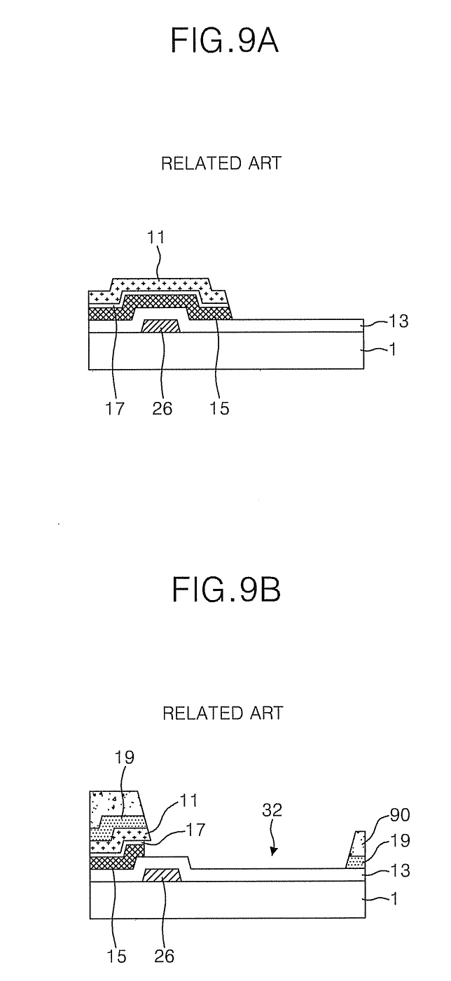

During an etching process for forming the first contact hole 154, the pixel hole 132 and the second contact hole 164, only the active layer is etched in the storage capacitor region. Therefore, an etching process time is reduced and an undercut phenomenon of the active layer can be prevented. This will now be described in more detail with reference to FIGS. 9A and 9B illustrating a conventional mask process. As illustrated in FIG. 9A, an active layer 15, an ohmic contact layer 17 and a drain electrode 11 having the same pattern are formed on a lower substrate 1 by the second mask process with a storage electrode 26 and a gate insulating layer 13 disposed therebetween. The active layer 15, the ohmic contact layer 17 and the drain electrode 11 are patterned by an etching process for about 40 to 50 seconds together with a passivation layer 19 by a photoresist pattern 90 during the third mask process, as shown in FIG. 9B, thereby generating an undercut phenomenon in the active layer 15 exposed by a pixel hole 32. However, in the present invention, the ohmic contact layer 116 and the drain electrode 110 are patterned during the second mask process, and only the active layer 114 is etched together with the passivation layer 118 during the third mask process. Therefore, the etching process time can be reduced to about 10 to 20 seconds, thus preventing the undercut phenomenon of the active layer. Then the step coverage of the pixel electrode 122 connected to the side surfaces of the semiconductor pattern and the drain electrode 110 exposed by the pixel hole 132 is improved and a shorting defect of the pixel electrode 122 is prevented.

As described above, in the TFT substrate and manufacturing method thereof according to the present invention, the active layer is exposed by patterning the ohmic contact layer and the drain electrode of the storage capacitor region during the second mask process. Since the exposed active layer is etched together with the passivation layer during the third mask process, the etching process time can be reduced and the undercut phenomenon of the active layer can be prevented. Therefore, the step coverage of the pixel electrode connected to the side surfaces of the semiconductor pattern and the drain electrode exposed by the pixel hole is improved and a shorting defect of the pixel electrode is prevented.

While the present invention has been shown and described with reference to a certain exemplary embodiments thereof, it will be understood by those skilled in the art that various changes in form and details may be made therein without departing from the spirit and scope of the present invention as defined by the appended claims.

What is claimed is:

1. A method of manufacturing a thin film transistor substrate, the method comprising:
a first mask process of forming a gate metal pattern including a gate line and a gate electrode connected to the gate line on a substrate;
a second mask process of forming a gate insulating layer covering the gate line and the gate electrode, a semiconductor pattern including an active layer and an ohmic contact layer on the gate insulating layer, and a source/drain metal pattern on the semiconductor pattern, the source/drain metal pattern including a data line defining a pixel region by intersecting the gate line, a source electrode connected to the data line, and a drain electrode exposing the active layer and facing the source electrode with a channel region disposed therebetween; and
a third mask process of forming a passivation layer covering the source/drain metal pattern, a pixel hole penetrating the active layer exposed by the passivation layer and by the drain electrode, and a pixel electrode connected to the drain electrode within the pixel hole.

2. The method of claim 1, wherein the first mask process further comprises forming a storage line overlapping the pixel electrode with the gate insulating layer disposed therebetween to form a storage capacitor.

3. The method of claim 2, wherein the semiconductor pattern adjacent to the storage line is exposed by the pixel hole to form a same width as the drain electrode or form a step shape with the drain electrode.

4. The method of claim 2, wherein the second mask process comprises:
depositing an amorphous silicon layer, an impurity doped amorphous silicon layer and a source/drain metal layer on the gate insulating layer;
forming a photoresist pattern having a step difference on the source/drain metal layer;
patterning the amorphous silicon layer, the impurity doped amorphous silicon layer and the source/drain metal layer by using the photoresist pattern;
removing the photoresist pattern of relatively thin thickness by ashing the photoresist pattern;
removing the source/drain metal layer and the impurity doped amorphous silicon layer of a storage capacitor region and of the channel region exposed by removing the photoresist pattern of relatively thin thickness; and
removing the photoresist pattern.

5. The method of claim 1, wherein the third mask process comprises:
forming a photoresist pattern on the passivation layer;
forming the pixel hole by etching the passivation layer and the active layer of the pixel region exposed through the photoresist pattern;
forming a transparent conductive layer on the passivation layer where the photoresist pattern exists; and
forming the pixel electrode by removing the photoresist pattern and the transparent conductive layer by a lift-off process.

6. A thin film transistor substrate, comprising:
a gate line formed on a substrate;
a data line defining a pixel region by intersecting the gate line with a gate insulating layer disposed therebetween;
a thin film transistor including a gate electrode connected to the gate line, a source electrode connected to the data line, a drain electrode facing the source electrode, and a semiconductor pattern forming a channel between the source electrode and the drain electrode;
a passivation layer covering the gate line, the data line and the thin film transistor;
a pixel hole of the pixel region, penetrating the passivation layer and an active layer included in the semiconductor pattern; and
a pixel electrode connected to the drain electrode within the pixel hole.

7. The thin film transistor substrate of claim 6, further comprising a storage line that is formed to cross the pixel region in parallel with the gate line and the storage line overlaps the pixel electrode with a gate insulating layer therebetween to form a storage capacitor.

8. The thin film transistor substrate of claim 7, wherein the semiconductor pattern adjacent to the storage line is exposed by the pixel hole to form a same width as the drain electrode or form a step shape with the drain electrode.
